(19) United States
(12) Patent Application Publication
(10) Pub. No.: US 2007/0262306 A1
(43) Pub. Date: Nov. 15, 2007

(54) Semiconductor device having microstructure and method of manufacturing microstructure

(75) Inventors: Naoki Ikeuchi, Amagasaki-shi (JP); Hiroyuki Hashimoto, Amagasaki-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: TOKYO ELECTRON LIMITED

(21) Appl. No.: 11/826,647

(22) Filed: Jul. 17, 2007

Related U.S. Application Data
(63) Continuation-in-part of application No. PCT/JP06/00615, filed on Jan. 18, 2006.

(30) Foreign Application Priority Data
Jan. 19, 2005 (JP) 2005-011850

(51) Int. Cl. H01L 23/58; B81C 3/00

(52) U.S. Cl. 257/48; 73/510; 73/509; 73/514.33; 324/765; 29/593

(57) ABSTRACT

A semiconductor device having a microstructure and a method of manufacturing a microstructure are provided, suppressing any change of characteristics in a wafer state caused in an assembly step. Specifically, a wafer where a plurality of microstructure chips are formed and a dummy wafer are attached to each other using an adhesive layer. As to an MEMS device, a cut dummy wafer is used as a mount for a chip and the dummy wafer and a housing member are attached to each other. Thus, the dummy wafer absorbs any stress or the like applied from below when the housing member is used for packaging.

### BACKGROUND OF THE INVENTION

1. Field of the Invention

The present invention relates to a semiconductor device having a microstructure such as MEMS (Micro Electro Mechanical Systems) for example, and to a method of manufacturing a microstructure.

2. Description of the Background Art

In recent years, MEMS which are devices where various functions such as mechanical, electronic, optical and chemical functions are integrated, particularly using the semiconductor microfabrication technology or the like, have been of interest. Some MEMS technologies have been put into practice so far, and MEMS devices are mounted as various types of sensors for automobiles and medical purposes for example, specifically microsensors such as acceleration sensor, pressure sensor and air flow sensor. Further, the MEMS technology can be applied to an inkjet printer head to increase the number of nozzles for ejecting ink and precisely eject the ink, and thereby improve the image quality and increase the print speed. Furthermore, a micro mirror array or the like that is used for a reflection type projector is also known as a common MEMS device.

In addition, a variety of sensors and actuators will be developed by utilizing the MEMS technology in the future, and it is expected that the technology will be further applied to optical communications and mobile devices, to peripheral devices of computers, and to biotechnological analysis and power sources for portable devices. A variety of MEMS technologies are introduced in Technology Research Report No. 3—Present Status of MEMS Technology and Related Issues (Ministry of Economy, Trade and Industry, Industrial Science and Technology Policy and Environment Bureau, Technology Research and Information Office and Manufacturing Industries Bureau, Industrial Machinery Division, Mar. 28, 2003).

Meanwhile, as the development of MEMS devices advances, a test for appropriately inspecting the fine structures or the like becomes more important.

Although characteristics of devices have conventionally been evaluated by rotating the devices after packaging or by using such means as vibration, an appropriate inspection can be conducted, for example, in the initial stage in the state of a wafer after being micromachined, so as to detect any defects and thereby improve the yield and further reduce the manufacturing cost.

FIG. 16 is a diagram illustrating that a plurality of MEMS chips formed on a wafer are cut in a dicing step and packaged.

As shown in FIG. 16, wafer 100 is diced with a dicing blade 101. Specifically, the wafer is cut with the dicing blade into separate chips CP. A chip CP as cut then undergoes an assembly step in which a housing member 110 and chip CP are attached to each other by means of an adhesive layer 120. Then, a wire WR is used to make wire bonding with a pad (not shown) disposed on chip CP.

However, in such a case as shown in FIG. 16 where housing member 110 and chip CP are directly attached to each other with adhesive layer 120 interposed therebetween, influences or the like (such as stress) of the assembly step could be directly exerted by housing member 110. A resultant problem is that the characteristics of the MEMS chip CP are caused to change from characteristics thereof in the wafer state.

Therefore, even if an element in the wafer state is regarded as non-defective, the element could be regarded defective in a package test or the like after the assembly step.

### SUMMARY OF THE INVENTION

The present invention has been made for solving the above-described problems, and an object of the invention is to provide a semiconductor device having a microstructure, suppressing any change of wafer-state characteristics caused by an assembly step, and to provide a method of manufacturing the microstructure.

A semiconductor device having a microstructure according to the present invention includes: a plurality of sensor chips formed on a first substrate undergoing a dicing step together with a second substrate and diced into sections for respective chips each including a microstructure having a movable element, the first substrate being attached, before the dicing step, to the second substrate using a first attachment layer, the second substrate being used as a mount for each of the sensor chips in a packaging step; a housing for housing each of the sensor chips and the mount for each of the sensor chips; and a second attachment layer used for attaching the mount for each of the sensor chips and the housing so as to house each of the sensor chips and the mount in the housing. A test is performed for evaluating an electrical characteristic that is output according to movement of a movable element of each of the plurality of sensor chips, and the test is performed in a state where the first substrate and the second substrate are attached to each other.

Preferably, the first attachment layer is formed in a region on the second substrate, and the region is a region except for a portion opposite to a region where the movable element of each of the sensor chips of the first substrate is formed.

Preferably, the second attachment layer is formed to provide a smaller area of attachment between the mount for each of the sensor chips and the housing than an area of the mount for each of the sensor chips.

Preferably, at least one of the first substrate and the second substrate corresponds to silicon substrate or glass substrate.

Preferably, each of the sensor chips corresponds to at least one of acceleration sensor, pressure sensor and microphone.

A method of manufacturing a microstructure according to the present invention includes the steps of: forming a plurality of sensor chips on a first substrate, the chips each including a microstructure having a movable element; attaching the first substrate and a second substrate using a first attachment layer, the second substrate being used as a mount for each of the sensor chips in a packaging step; performing a test for evaluating an electrical characteristic that is output according to movement of the movable element of each of the plurality of sensor chips in a state where the first substrate and the second substrate are attached to each other; dividing the first substrate and the second substrate attached to each other into sections for respective sensor chips by dicing; and attaching the mount for each of the sensor chips and a housing to each other using a second attachment layer for housing each of the sensor chips on the first substrate and the second substrate and the mount for each of the sensor chips in the housing in the packaging step after the dicing.

Preferably, the first attachment layer is formed in a region on the second substrate, and the region is a region except for a portion opposite to a region where the movable element of each of the sensor chips of the first substrate is formed.

Preferably, the second attachment layer is formed to provide a smaller area of attachment between the mount for each of the sensor chips and the housing than an area of the mount for each of the sensor chips.

Preferably, the step of performing the test includes the step of vacuum-sucking the second substrate and transferring the second substrate to an inspection unit.

As to the semiconductor device having the microstructure and the method of manufacturing the microstructure according to the present invention, a first wafer where a plurality of sensor chips each including a microstructure having a movable element is attached to a second wafer used as a mount for each sensor chip in a packaging step after a dicing step. Accordingly, a stress or the like generated during packaging can be absorbed by the mount so that the packaging can be accomplished without causing characteristics in the wafer state to change.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a conceptual diagram illustrating a method of manufacturing a microstructure according to an embodiment of the present invention.

FIG. 2 is a diagram illustrating a flow of attaching a dummy wafer 10 and a wafer 100 to each other.

FIG. 3 shows a three-axis acceleration sensor as seen from above the device.

FIG. 4 is a schematic diagram of the three-axis acceleration sensor.

FIG. 5 is a conceptual diagram illustrating deformation of proof masses and beams when acceleration is applied in the direction of each axis.

FIG. 6 is a circuit configuration diagram of a Wheatstone bridge provided for each axis.

FIG. 7 illustrates a relation between a gravitational acceleration (input) and a sensor output.

FIG. 8 is a conceptual diagram illustrating an adhesive layer selectively formed on dummy wafer 10.

FIG. 9 is a diagram illustrating attachment of a chip unit CPU and a housing member 110 to each other in a packaging step.

FIG. 10 is a diagram illustrating a wafer test conducted on wafer 100.

FIG. 11 is a schematic block diagram illustrating an inspection apparatus 30 conducting a wafer test.

FIG. 12 is a schematic configuration diagram illustrating an inspection unit 36.

FIG. 13 is a diagram illustrating a part of a wafer holding unit 35.

FIG. 14 is a diagram illustrating a wafer sucked by a vacuum pump 18.

FIG. 15 is a diagram illustrating a microphone as an example of the capacitive-sensor-type sensing device.

FIG. 16 is a diagram illustrating that a plurality of MEMS chips formed on a wafer are cut in a dicing step and packaged.

### DESCRIPTION OF THE PREFERRED EMBODIMENTS

In the following, embodiments of the present invention will be described in detail with reference to the drawings. In the drawings, like or corresponding components are denoted by like reference characters and a description thereof will not be repeated.

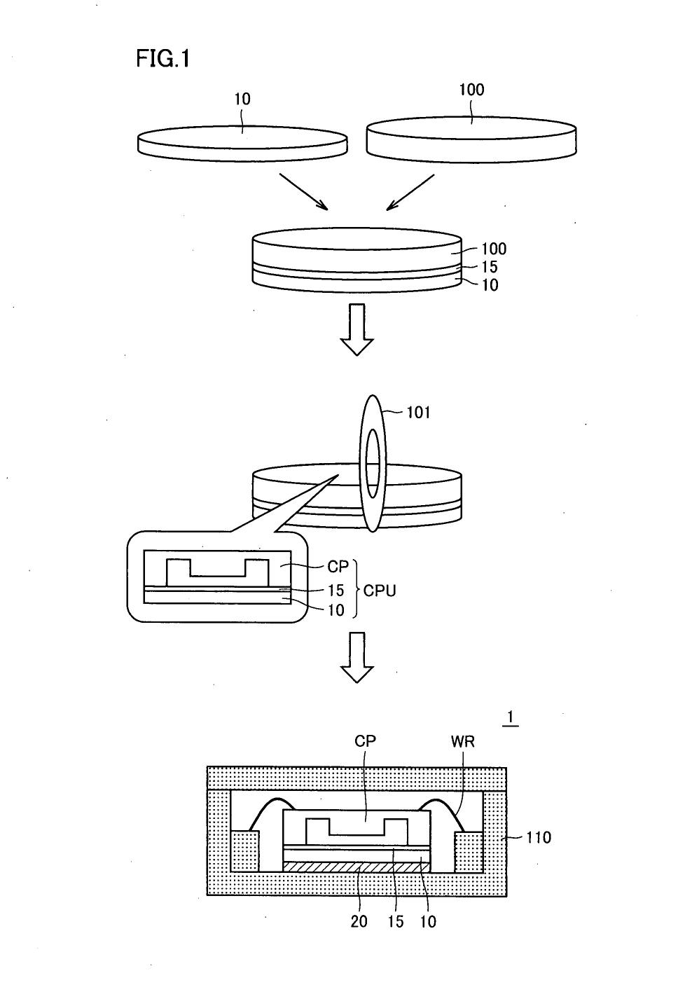

FIG. 1 is a conceptual diagram illustrating a method of manufacturing a microstructure according to an embodiment of the present invention.

Referring to FIG. 1, the method of manufacturing a microstructure in the embodiment of the present invention uses an adhesive layer 15 for a wafer 100 where a plurality of chips CP of microstructures are formed, so as to bond wafer 100 to a dummy wafer 10.

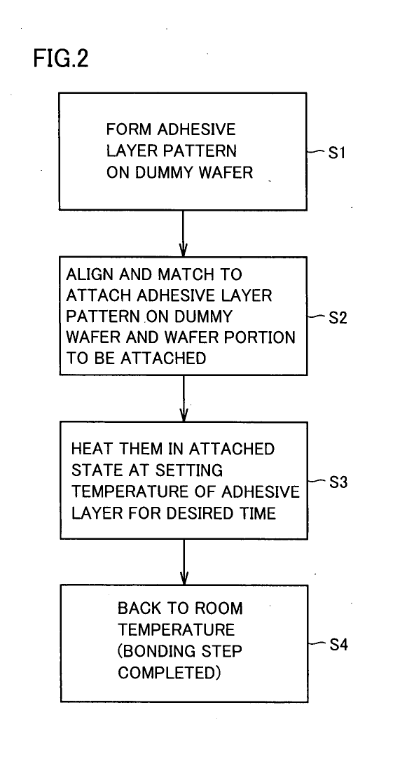

FIG. 2 is a diagram illustrating a flow of attaching dummy wafer 10 and wafer 100 to each other.

Referring to FIG. 2, the pattern of the adhesive layer is formed on dummy wafer 10 (step S1). Then, the adhesive layer pattern on the dummy wafer and a corresponding portion of wafer 100 to be attached are aligned and matched with each other, and then they are attached to each other (step S2). The alignment is a common technique and a detailed description thereof is not given here.

Next, these in the attached state are heated at a setting temperature of the adhesive layer for a desired time (step S3). Accordingly, the state of attachment between dummy wafer 10 and wafer 100 is strengthened. The temperature is decreased back to room temperature (step S4). In this way, the step of bonding wafer 100 and dummy wafer 10 to each other is completed. Here, the degree of attachment may be increased by heating at least one of dummy wafer 10 and wafer 100 when they are attached to each other. Here, for the adhesive layer, silicon resin, urethane resin, acrylic resin, polyamide resin, polyimide resin, flexible epoxy resin, or the like may be used for example.

Referring again to FIG. 1, wafer 100 and dummy wafer 10 bonded to each other are cut with a dicing blade 101 into chip-shaped portions. Then, in an assembly step, a chip unit CPU which is a chip-shaped portion as cut and a housing member 110 are attached to each other by means of an adhesive layer 20. Here, chip unit CPU is composed of a chip CP formed by cutting wafer 100 and the cut adhesive layer 15 and dummy wafer 10.

Then, as described above, a wire WR is used to make wire bonding with a desired terminal (not shown) formed on chip CP, and an MEMS device 1 as packaged is fabricated.

In connection with the present invention, a three-axis acceleration sensor which is a multi-axis sensor is described as an example of the chip CP of a microstructure having a movable element.

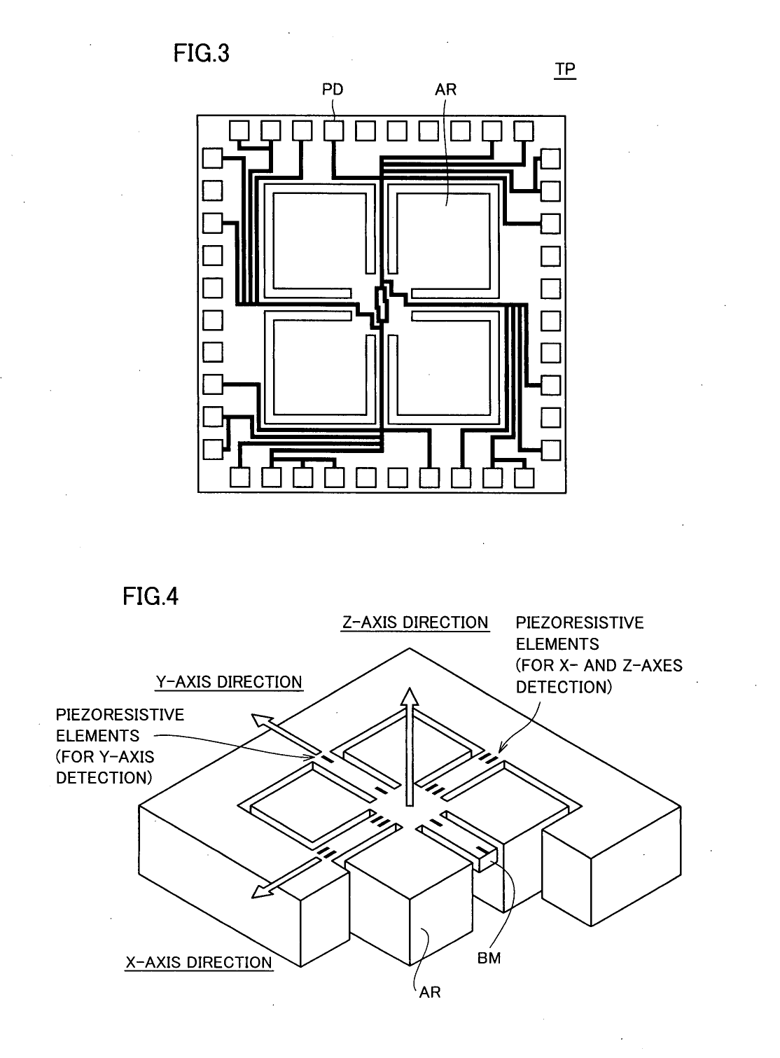

FIG. 3 is a diagram of the three-axis acceleration sensor as seen from above the device.

As shown in FIG. 3, chip CP has a plurality of pads PD arranged on its periphery. Further, a metal interconnect is disposed for transmitting an electrical signal to a pad PD or from pad PD. In a central portion, four proof masses AR in the form of a clover are arranged.

FIG. 4 is a schematic diagram of the three-axis acceleration sensor.

With reference to FIG. 4, the three-axis acceleration sensor is a piezoresistive sensor, and a piezoresistive element which is a detection element is provided as a diffused resistor. This piezoresistive acceleration sensor can be made using a low-cost IC process, and the sensitivity does not deteriorate even if the resistor element that is a detection element is small-sized. Therefore, this acceleration sensor is advantageous for downsizing and for reducing the cost.

As to the specific configuration, proof masses AR in the central portion are structured to be supported by four beams BM. Beams BM are formed to extend perpendicularly to each other in the two axial directions of X and Y, and four piezoresistive elements are provided for each axis. The four piezoresistive elements for detection in the Z-axis direction are provided on the side of the piezoresistive elements for detection in the X-axis direction.

Proof masses AR have the upper surface in the shape of a four-leafed clover, and are coupled with beams BM in the central portion. This clover-shape structure can be employed to increase the size of proof masses AR and simultaneously increase the length of the beams. Therefore, the acceleration sensor which is highly sensitive in spite of its small size can be implemented.

As to the principle of operation of the piezoresistive three-axis acceleration sensor, the sensor has a mechanism as follows. Acceleration (inertial force) is exerted on the proof masses, which causes beams BM to deform and thereby changes the resistance value of the piezoresistive elements formed on the surface of the beams and, according to the change of the resistance value, the acceleration is detected. The output of the sensor is obtained from an output of a Wheatstone bridge described hereinlater that is incorporated independently into each of the three axes.

FIG. 5 is a conceptual diagram illustrating deformation of the proof masses and beams when acceleration is applied in the direction of each axis.

As shown in FIG. 5, a piezoresistive element has the property that the resistance value thereof is changed due to applied strain (piezoresistive effect). The resistance value increases when tensile stain is applied while the resistance value decreases when compressive strain is applied. In the present embodiment, piezoresistive elements for detection in the X-axis direction Rx1 to Rx4, piezoresistive elements for detection in the Y-axis direction Ry1 to Ry4 and piezoresistive elements for detection in the Z-axis direction Rz1 to Rz4 are shown as examples.

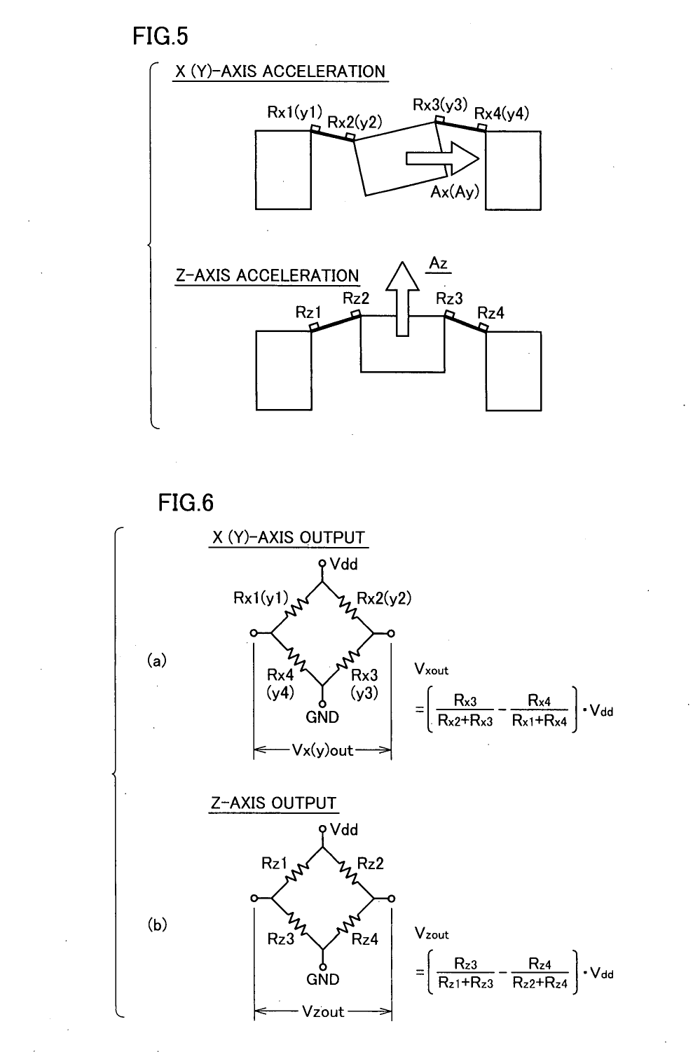

FIG. 6 is a circuit configuration diagram of a Wheatstone bridge provided for each axis.

FIG. 6 (a) is a circuit configuration diagram of a Wheatstone bridge of the X (Y) axis.

The output voltages of the X axis and the Y axis are represented by Vxout and Vyout, respectively.

FIG. 6 (b) is a circuit configuration diagram of a Wheatstone bridge of the Z axis.

The output voltage of the Z axis is represented by Vzout.

As described above, the resistance values of the four piezoresistive elements along each axis change due to applied strain and, on the basis of this change, the output of the circuit configured with the Wheatstone bridge for the piezoresistive elements in the X and Y axes for example is detected as an output of an independent and separate acceleration component of each axis. Here, the above-described metal interconnects or the like as shown in FIG. 3 are coupled to configure the above-described circuit, and an output voltage for each axis is detected from a predetermined pad.

In addition, the three-axis acceleration sensor can also detect the DC component of acceleration, and therefore, the three-axis acceleration sensor may also be used as an inclination sensor detecting the gravitational acceleration.

FIG. 7 illustrates a relation between a gravitational acceleration (input) and a sensor output.

As shown in FIG. 7, the output voltage (mV) according to the gravitational acceleration (input) can be detected.

As described above, MEMS device 1 of the present invention has the cut dummy wafer 10 which is used as a mount for chip CP and attached to housing member 110. Therefore, dummy wafer 10 can be used to absorb any stress or the like applied from below when housing 110 is used for packaging.

Accordingly, although the movable elements, namely proof masses AR and beams BM could be deformed due to stress applied during packaging, the configuration here enables the stress to be absorbed by dummy wafer 10 and thus any change, caused in the assembly step, of the characteristics in the wafer state can be suppressed.

In this way, such a case can be suppressed where elements regarded as non-defective in a wafer test for example are then regarded as defective in a package test after the assembly step, and accordingly the yield can be improved. Further, the test results of the wafer test can be used effectively.

Here, dummy wafer 10 used herein is formed using a material having the same thermal expansion coefficient as wafer 100 where chip CP is formed. In other words, dummy wafer 10 may be formed using a silicon (Si) material.

Thus, the dummy wafer is used as a mount that is made of a material having the same thermal expansion coefficient as the wafer. Therefore, any adverse effect due to strain caused by a difference between respective thermal expansion coefficients can be removed.

It has been described above that adhesive layer 15 is used to attach dummy wafer 10 and wafer 100 to each other. Instead of forming the adhesive layer on the entire surface of dummy wafer 10, the adhesive layer may be selectively formed on the dummy wafer.

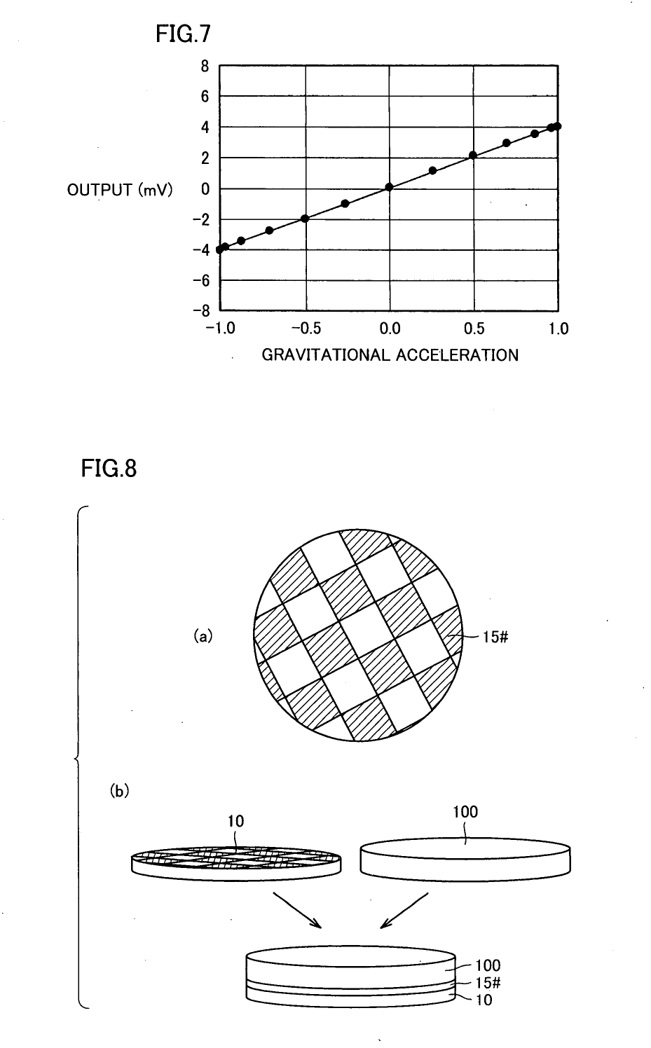

FIG. 8 is a conceptual diagram illustrating the adhesive layer selectively formed on dummy wafer 10.

FIG. 8 (a) illustrates an adhesive layer 15# formed on dummy wafer 10 according to a predetermined pattern.

FIG. 8 (b) illustrates attachment of dummy wafer 10 and wafer 100 to each other.

As shown in FIG. 8 (b), wafer 100 and dummy wafer 10 are attached to each other with the aforementioned adhesive layer 15# interposed therebetween.

For example, in this embodiment, a pattern is formed so that the adhesive layer is selectively formed in a region except for a region opposite to a region where such movable elements of the microstructure in chip CP as proof masses AR and beams BM.

Thus, the risk of attachment of the movable elements by adhesive layer 15# in the step of attaching dummy wafer 10 and wafer 100 to each other can also be avoided.

As to a method of patterning, various methods are available. For example, screen printing method with an adhesive paste for example, namely the method according to which the paste is printed on the mask, or dispensing method of dispensing the adhesive paste to a selected portion, namely the method according to which a certain amount of paste is pushed out from a nozzle by means of a pressure of air for example, or the method according to which patterning by photolithography is performed using a photosensitive adhesive, or the method according to which the attachment is made using an adhesive sheet (tape) in which punch holes are made in unnecessary portions, may be employed.

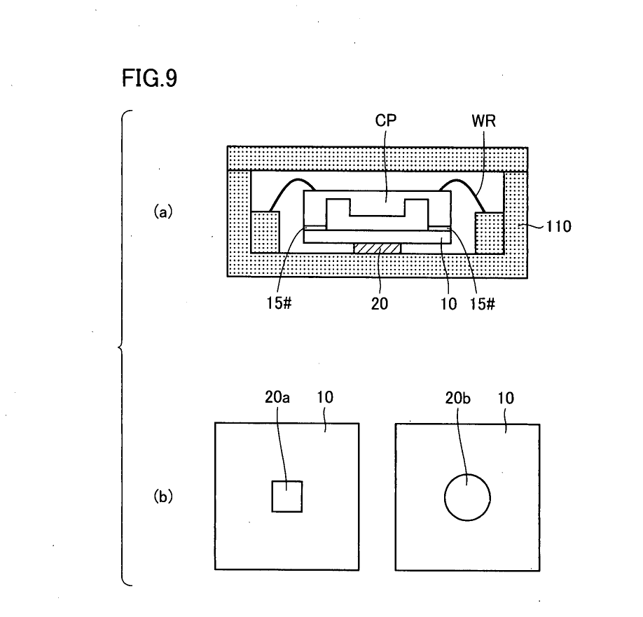

FIG. 9 is a diagram illustrating attachment of chip unit CPU and housing member 110 to each other in the packaging step.

As shown in FIG. 9 (a), adhesive layer 20 is used to attach housing member 110 and chip unit CPU to each other, and the area of attachment can be made smaller than the area of dummy wafer 10 which is the mount for sensor chip CP. By providing the smaller attachment area, transmission can be further suppressed of the stress, which is an influence of the assembly step, of housing member 110 to chip CP. In the present embodiment, an adhesive layer 15# is selectively formed to allow chip CP and dummy wafer 10 to be attached to each other in a region other than the region of the movable elements.

FIG. 9 (b) schematically illustrates the adhesive layer formed between dummy wafer 10 and housing member 110.

As shown in FIG. 9 (b), an adhesive layer 20a formed according to the rectangular patterning may be used to attach chip unit CPU and housing member 110 to each other, or an adhesive layer 20b according to the circular patterning may be used to attach chip unit CPU and housing member 110 to each other. In the present embodiment, while the adhesive layer as illustrated is formed in a single region, the embodiment is not limited to this. Alternatively, the adhesive layer may be formed in a plurality of regions.

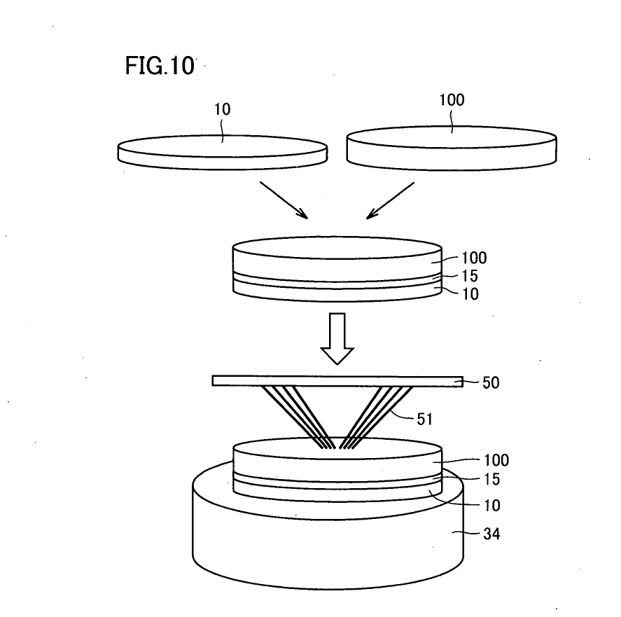

FIG. 10 is a diagram illustrating a wafer test conducted on wafer 100.

Referring to FIG. 10, according to the present invention, the wafer test is conducted in the state where wafer 100 and dummy wafer 10 are attached to each other with adhesive layer 15 therebetween.

Specifically, onto a measurement vacuum suck chuck 34 (hereinafter simply referred to as chuck), wafer 100 and dummy wafer 10 are transferred, and a probe card 50 having a probe needle 51 is used to conduct a characteristic inspection of chip CP formed on wafer 100.

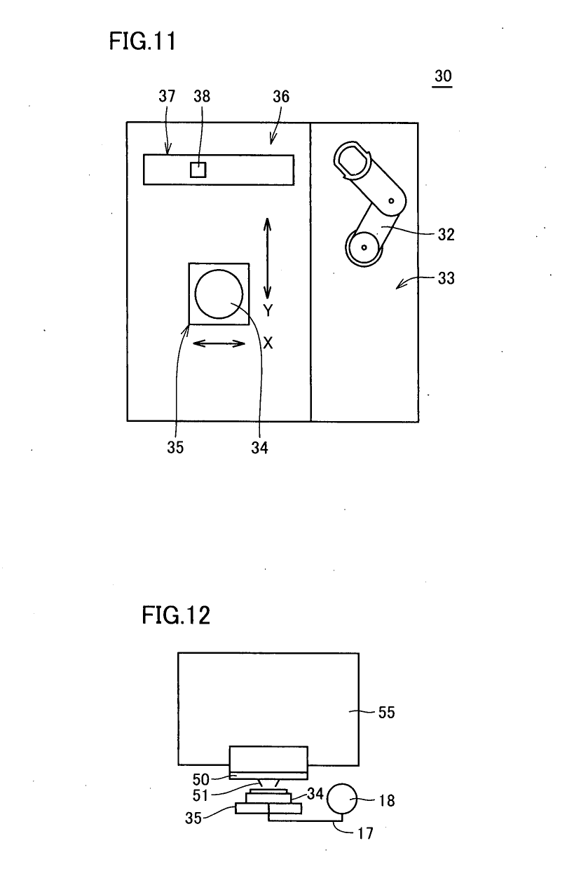

FIG. 11 is a schematic block diagram illustrating an inspection apparatus 30 performing a wafer test.

Referring to FIG. 11, inspection apparatus 30 has its main portion composed of a rotor unit 33 having a transfer arm 32 transferring a wafer to be inspected, an inspection unit 36 and a wafer holding unit 35. In this case, transfer arm 32 disposed in rotor unit 33 is formed with a multi-joint link mechanism that is horizontally rotatable and vertically movable, and configured to transfer a wafer taken from a cassette (not shown) containing a plurality of wafers to wafer holding unit 35 and transfers the wafer inspected by inspection unit 36 back to the cassette. The wafer taken from the cassette by transfer arm 32 is transferred to chuck 34 of wafer holding unit 35. Wafer holding unit 35 keeps this state and transfers the wafer to inspection unit 36. In inspection unit 36, the position of the transferred wafer is detected using a position detection camera 38 or the like of an alignment apparatus 37. Based on the information about the position as detected, alignment is performed and positional adjustment or the like is made for allowing probe needle 51 to contact a desired test pad.

FIG. 12 is a schematic configuration diagram illustrating inspection unit 36.

Referring to FIG. 12, probe card 50 to which probe needle 51 is attached is connected to a test head 55.

Test head 55 is formed of a self-contained columnar body mounted with electrical devices (not shown) such as a power supply for inspection for supplying power to wafer 100, a pattern output unit for an electrode pad and an input unit for taking an output of the electrode pad into a measurement unit.

Wafer holding unit 35 includes a vacuum pump 18 which is suck means connected to chuck 34 via a flexible tube 17.

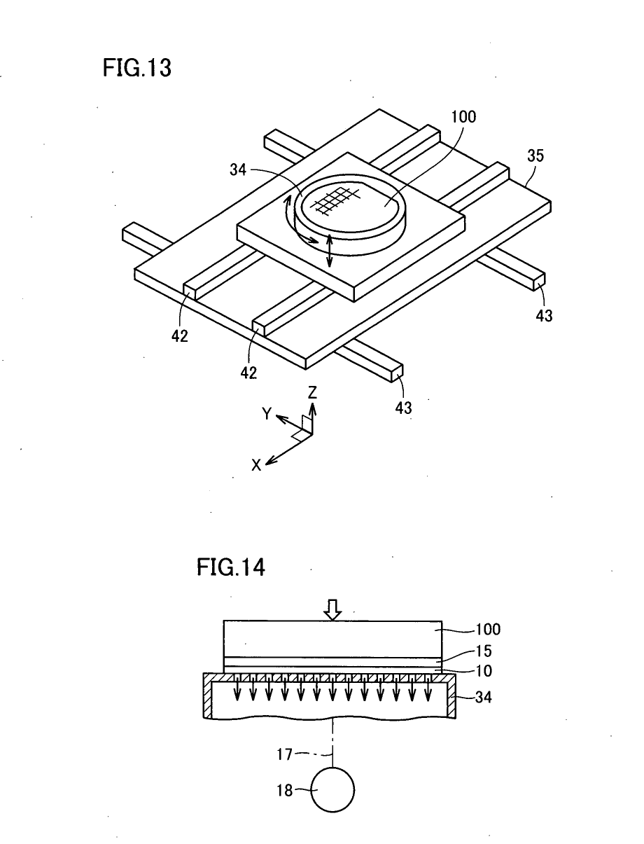

FIG. 13 is a diagram illustrating a part of wafer holding unit 35.

As shown in FIG. 13, it is composed of a Y stage guided in a slidable manner by a Y-direction guide rail 43 disposed in the Y-direction, an X stage guided in a slidable manner by an X-direction guide rail 42 provided on the Y stage in the direction orthogonal to the Y direction, namely the X direction, and chuck 34 attached to be movable up-and-down (in the Z direction) with respect to the X stage and rotatable. In this case, chuck 34 is formed to be hollow having a small sucking hole (not shown), and vacuum pump 18, which is sucking means, is connected via flexible tube 17 to the hollow portion of chuck 34.

FIG. 14 is a diagram illustrating a wafer sucked by vacuum pump 18.

As shown in FIG. 14, vacuum pump 18 is actuated to generate a negative pressure in the hollow portion of chuck 34, so that wafer 100 and dummy wafer 10 can be sucked and held.

As to the configuration of the present embodiment, when wafer holding unit 35 sucks the wafer by vacuum, dummy wafer 10 is sucked and transferred. In other words, since wafer 100 where the above-described acceleration sensor is formed 100 has a through portion, the wafer cannot be directly transferred by means of such vacuum suck of vacuum pump 18.

In contrast, dummy wafer 10 like that of the present invention can be attached to allow dummy wafer 10 which has no through portion to be vacuum-sucked, and accordingly a wafer test can be conducted on wafer 100 without the necessity of a particular apparatus.

The embodiment has been described regarding chip CP formed for the acceleration sensor. The present invention, however, is not limited to the acceleration sensor and applicable to MEMS devices having other types of movable elements.

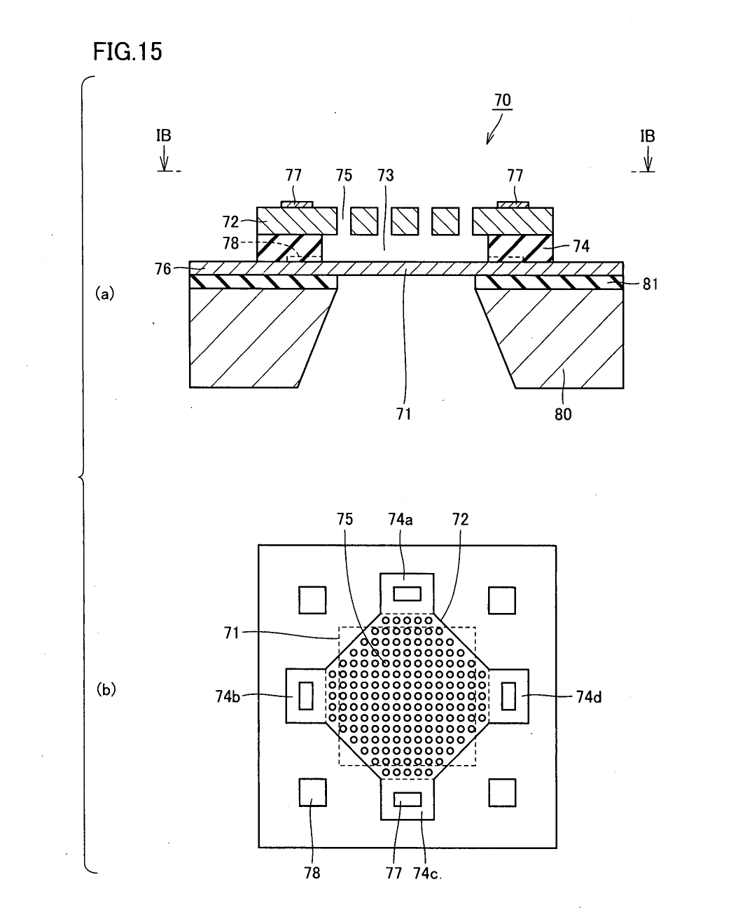

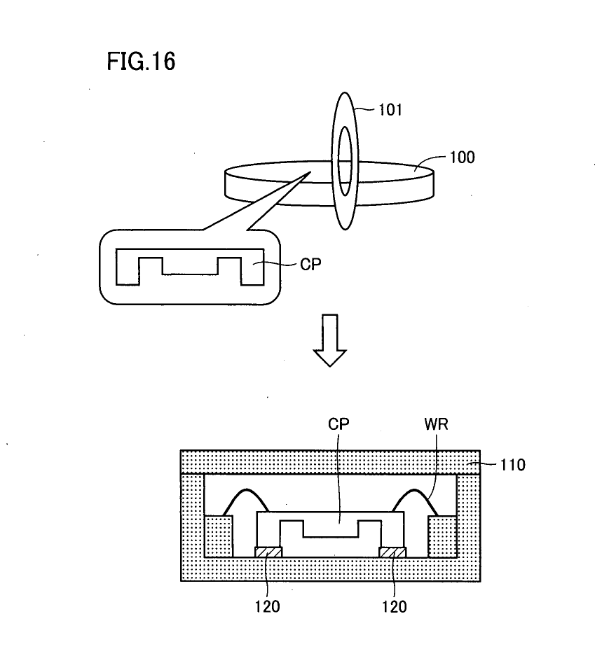

FIG. 15 is a diagram illustrating a microphone as an example of the capacitive-sensor-type sensing device.

Referring to FIG. 15 (a), microphone 70 includes a substrate 80, an oxide film 81 formed on substrate 80, a vibration plate 71 (including an extended portion 76 extending outward with respect to the vibration plate) formed on oxide film 81, a fixed portion 74 provided on vibration plate 71 and formed of an insulating material, and a back electrode 72 provided on fixed portion 74. Fixed portion 74 forms a space 73 between vibration plate 71 and back electrode 72. Back electrode 72 has a plurality of through holes provided as acoustic holes 75. On a surface of back electrode 72, an output electrode 77 for the back electrode is provided. On a surface of extended portion 76 of vibration plate 71, an output electrode 78 for the vibration plate is provided.

Referring next to FIG. 15 (b), vibration plate 71 is provided in a substantially central portion of substrate 80 and is rectangular in shape. Here, for simplifying illustration, the shape of the plate is described as a square. In substantially central parts of respective four sides that constitute vibration plate 71, four rectangular fixed portions 74a to 74d are provided adjacent to the respective sides, and back electrode 72 is provided on fixed portions 74. Back electrode 72 is in the shape of an octagon including respective four sides of fixed portions 74 that face the vibration plate and the four sides (straight lines) each connecting adjacent vertices of fixed portions 74 (the shortest distance between 74a and 74b for example).

Since back electrode 72 is supported by fixed portions 74 provided on the outer peripheral portion of the four sides of vibration plate 71 and since it has the shape composed of the shortest distances between adjacent vertices of fixed portions 74, the mechanical strength of back electrode 72 can be ensured.

Here, although FIG. 15 (b) shows the space between vibration plate 71 and fixed portion 74 for ease of understanding, actually there is almost no space therebetween.

Further, although FIG. 15 (b) shows four electrodes 77 for the back electrode provided on respective fixed portions 74 and four electrodes 78 for the vibration plate provided at the four corners of the surface of extended portion 76 of vibration plate 71, they are provided in consideration of the yield and the number of the former electrodes and the number of the latter electrodes may be one each.

Vibration plate 71 receives a pressure change (including sound or the like) from the outside to vibrate. Specifically, microphone 70 operates using vibration plate 71 and back electrode 72 as a capacitor. The microphone can be used in the manner of electrically taking a change in electrostatic capacitance of the capacitor while vibration plate 71 is vibrated by a sound pressure signal.

In connection with the present embodiment, the microphone is described as an example. The invention, however, is not limited to this and applicable to an arbitrary capacitive sensor element such as pressure sensor.

Further, the description above explains the case where dummy wafer 10 of the same material as that of wafer 100 is attached to wafer 100 for using the dummy wafer as a mount for wafer 100. Dummy wafer 10 used as a mount may be replaced for example with a glass substrate. With this structure as well, stress or the like generated during packaging can be absorbed by the mount.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor device having a microstructure comprising:
a plurality of sensor chips formed on a first substrate undergoing a dicing step together with a second substrate and diced into sections for respective chips each including a microstructure having a movable element,
said first substrate being attached, before said dicing step, to said second substrate using a first attachment layer, said second substrate being used as a mount for each said sensor chips in a packaging step;
a housing for housing each said sensor chips and the mount for each said sensor chips; and
a second attachment layer used for attaching the mount for each said sensor chips and said housing so as to house each said sensor chips and the mount in said housing, wherein
a test is performed for evaluating an electrical characteristic that is output according to movement of a movable element of each said plurality of sensor chips, and said test is performed in a state where said first substrate and said second substrate are attached to each other.

2. The semiconductor device having the microstructure according to claim 1, wherein
said first attachment layer is formed in a region on said second substrate, and the region is a region except for a portion opposite to a region where said movable element of each said sensor chips of said first substrate is formed.

3. The semiconductor device having the microstructure according to claim 1, wherein
said second attachment layer is formed to provide a smaller area of attachment between the mount for each said sensor chips and said housing than an area of the mount for each said sensor chips.

4. The semiconductor device having the microstructure according to claim 1, wherein
at least one of said first substrate and said second substrate corresponds to silicon substrate or glass substrate.

5. The semiconductor device having the microstructure according to claim 1, wherein
each said sensor chips corresponds to at least one of acceleration sensor, pressure sensor and microphone.

6. A method of manufacturing a microstructure comprising the steps of
forming a plurality of sensor chips on a first substrate, said chips each including a microstructure having a movable element;
attaching said first substrate and a second substrate using a first attachment layer, said second substrate being used as a mount for each said sensor chips in a packaging step;
performing a test for evaluating an electrical characteristic that is output according to movement of the movable element of each said plurality of sensor chips in a state where said first substrate and said second substrate are attached to each other;
dividing said first substrate and said second substrate attached to each other into sections for respective sensor chips by dicing; and
attaching the mount for each said sensor chips and a housing to each other using a second attachment layer for housing each said sensor chips on said first substrate and said second substrate and the mount for each said sensor chips in said housing in said packaging step after the dicing.

7. The method of manufacturing a microstructure according to claim 6, wherein
said first attachment layer is formed in a region on said second substrate, and the region is a region except for a portion opposite to a region where said movable element of each said sensor chips of said first substrate is formed.

8. The method of manufacturing a microstructure according to claim 6, wherein
said second attachment layer is formed to provide a smaller area of attachment between the mount for each said sensor chips and said housing than an area of the mount for each said sensor chips.

9. The method of manufacturing a microstructure according to claim 6, wherein
said step of performing the test includes the step of vacuum-sucking said second substrate and transferring said second substrate to an inspection unit.
